(19) United States
(12) Patent Application Publication
(10) Pub. No.: US 2022/0002144 A1
(43) Pub. Date: Jan. 6, 2022

(54) MEMS CONDUCTIVE MEMBER AND PREPARATION METHOD OF CONDUCTIVE COATING LAYERS

(71) Applicant: AAC ACOUSTIC TECHNOLOGIES (SHENZHEN) CO., LTD., Shenzhen (CN)

(72) Inventors: Lanlan Tu, Shenzhen (CN); Wooicheang Goh, Singapore (SG); Kahkeen Lai, Singapore (SG); Ze Tao, Shenzhen (CN)

(21) Appl. No.: 17/138,901

(22) Filed: Dec. 31, 2020

(30) Foreign Application Priority Data
Jul. 6, 2020 (CN) 202010642924.7

(51) Int. Cl. B81B 7/00; B81B 3/00

(52) U.S. Cl. CPC B81B 7/0006; B81B 2201/0257; B81B 7/008; B81B 3/0086

(57) ABSTRACT

The invention provides a method for preparing a MEMS conductive part and a conductive coating. A conductive unit includes a fixed member, a moving member which can reciprocate relative to the fixed member, and a plurality of groups of conductive electroplating layers which are electrically connected with the moving member and the fixed member, the moving member includes a first wall and a second wall connected with the first wall, and the fixed member includes a first wall connected with the first wall. The end components (fixed and moving components) displace relatively freely and transmit electric signals at the same time.

### FIELD OF THE PRESENT DISCLOSURE

The invention relates to the technical field of loudspeaker preparation processes, in particular to a MEMS conductive member and a preparation method of conductive coating layers.

### DESCRIPTION OF RELATED ART

A MEMS conductive member is a very important element for signal transmission between a MEMS sensor and a printed circuit board. The high-quality MEMS conductive member is essential to ensure stable and efficient signal transmission.

In a preparation process of the MEMS conductive member in the prior art, the MEMS conductive member with thick conductive coating layers is usually prepared by using a chemical electroplating process. In the prior art, as shown in FIG. 5, the preparation of metal coating layers 101 is usually completed by electroplating thick metal into a substrate 102 with deep trenches 104 and carrying out etching. However, in this preparation method, photoresists cannot be completely aligned with the metal coating layers 101 in a plasma etching process, some photoresists 103 cannot completely cover the metal coating layers 101 and some photoresists 103 excessively cover the metal coating layers 101 and extend to the substrate 102 at the sides of the metal coating layers 101, so that the metal coating layers 101 which are not covered with the photoresists 103 are easily damaged in the etching process, and furthermore, the substrate 102 covered with the photoresists 103 remains after the etching; and these problems will affect the rigidity and processing capacity of the MEMS conductive member.

Therefore, it is necessary to provide a novel MEMS conductive member and a related preparation method thereof to solve the problems.

### SUMMARY OF THE INVENTION

One of the objects of the invention is to provide a preparation method of MEMS conductive parts, which optimizes the preparation method of MEMS conductive parts in the prior art to obtain flexible parts with good conductivity and stable processing ability.

Accordingly, the present invention provides a MEMS conductive member including multiple conductive units each comprising a fixed member, a movable member capable of reciprocating relative to the fixed member, and multiple groups of conductive coating layers of electrically connecting the movable member and the fixed member; wherein

each movable member comprises a first surrounding wall and a second surrounding wall connected with the first surrounding wall;

each fixed member comprises a third surrounding wall arranged opposite to the first surrounding wall, and a fourth surrounding wall connected with the third surrounding wall and arranged opposite to the second surrounding wall;

and the multiple groups of conductive coating layers are arranged at intervals and extend to the third surrounding walls from the first surrounding walls respectively.

In addition, the conductive coating layers extend to the third surrounding walls from the first surrounding walls in a bent and detoured manner respectively.

In addition, projections of the conductive units in the direction perpendicular to the extension directions of the conductive coating layers are rectangular; the MEMS conductive member is composed of four conductive units; four movable members form an H-shape member as a whole; every two fixed members form a T-shape member as a whole; two T-shape members are positioned at two sides of the H-shape member respectively; and the H-shape member can reciprocate relative to the two T-shape members.

The invention further provides a preparation method of the conductive coating layers comprising steps of:

S1, providing a substrate, wherein the substrate is depressed to form a bottom wall, and one first surrounding wall, one second surrounding wall, one third surrounding wall and one fourth surrounding wall surrounding the bottom wall; and the surfaces of the bottom wall, the first surrounding wall, the second surrounding wall, the third surrounding wall and the fourth surrounding wall are covered with a seed layer;

S2, forming a seed layer at one sides, far away from the bottom wall, of the first surrounding wall, the second surrounding wall, the third surrounding wall and the fourth surrounding wall is removed to expose the first surrounding wall, the second surrounding wall, the third surrounding wall and the fourth surrounding wall;

S3, enclosing the bottom wall, the first surrounding wall, the second surrounding wall, the third surrounding wall and the fourth surrounding wall for forming a conductive coating space, wherein photoresists arranged at intervals are formed in the conductive coating space, and the photoresists protrude in the direction far away from the bottom wall from the seed layer;

S4, coating the conductive coating layers in the conductive coating space, wherein the conductive coating layers protrude in the direction far away from the bottom wall from the seed layer;

S5, stripping the photoresists, wherein the seed layer covered with the photoresists is exposed and the exposed seed layer is removed; and

S6, etching the bottom wall for suspending the conductive coating layers.

In addition, a chemical mechanical polishing process is adopted in the step S2 to remove the seed layer at one sides, far away from the bottom wall, of the first surrounding wall, the second surrounding wall, the third surrounding wall and the fourth surrounding wall to expose the first surrounding wall, the second surrounding wall, the third surrounding wall and the fourth surrounding wall.

In addition, the thicknesses of the photoresists in the step S3 are set to be 20-100 microns.

In addition, the photoresists are sprayed in the conductive coating space, and the photoresists arranged at intervals are etched after exposure and development.

In addition, the viscosity of the photoresists is greater than or equal to 6,000 centipoises.

In addition, the seed layer is a metal layer which is the same as the conductive coating layers in material.

### BRIEF DESCRIPTION OF THE DRAWINGS

Many aspects of the exemplary embodiments can be better understood with reference to the following drawings. The components in the drawing are not necessarily drawn to scale, the emphasis instead being placed upon clearly illustrating the principles of the present disclosure.

FIG. 1 is a structure diagram of a MEMS conductive member in an embodiment of the invention.

FIG. 2 is the structure diagram of a conductive unit in the embodiment of the invention.

FIG. 3 is a process diagram of a preparation method of conductive coating layers in the embodiment of the invention.

FIG. 4 is a flowchart of the preparation method of the conductive coating layers in the embodiment of the invention.

FIG. 5 is the process diagram of the preparation method of the MEMS conductive member in the prior art.

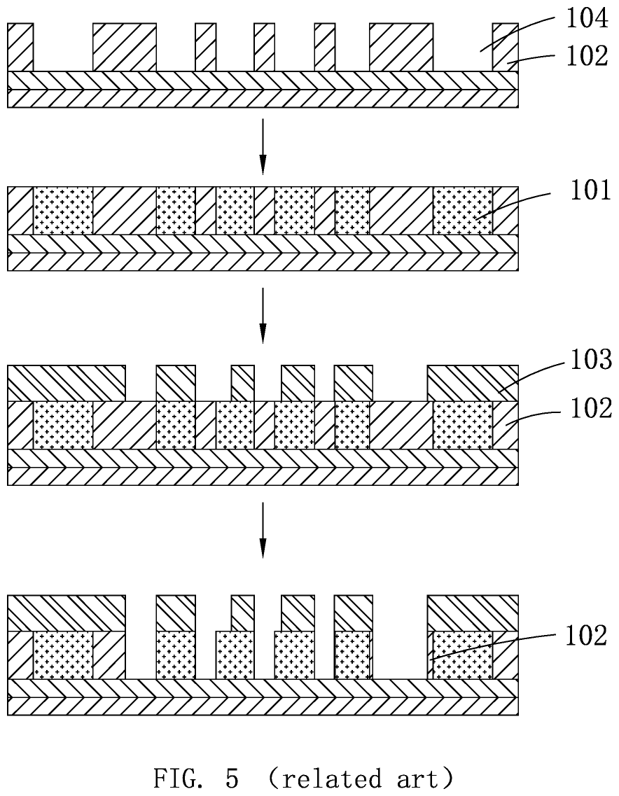

### DETAILED DESCRIPTION OF THE EXEMPLARY EMBODIMENTS

The present disclosure will hereinafter be described in detail with reference to several exemplary embodiments. To make the technical problems to be solved, technical solutions and beneficial effects of the present disclosure more apparent, the present disclosure is described in further detail together with the figure and the embodiments. It should be understood the specific embodiments described hereby is only to explain the disclosure, not intended to limit the disclosure.

It should be noted that, all directional instructions in the embodiment of the invention (such as upper, lower, left, right, front, rear, inside, outside, top and bottom) are used only for explaining relative positional relationships between various components in a particular attitude (as shown in the drawings), and the like. If the particular attitude is changed, the directional instructions are changed accordingly.

It should be further noted that, when an element is referred to as being “fixed” or “arranged” on another element, it may be directly on the other element or intervening elements may be present at the same time. When an element is referred to as being “connected” on another element, it may be directly connected to the other element or intervening elements may be present at the same time.

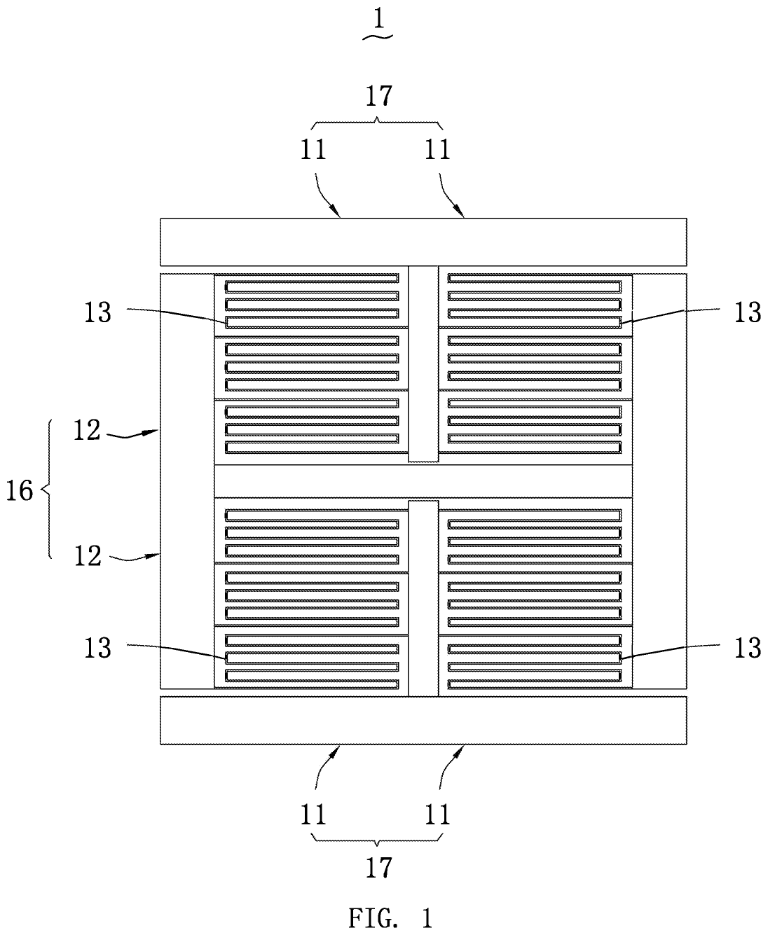

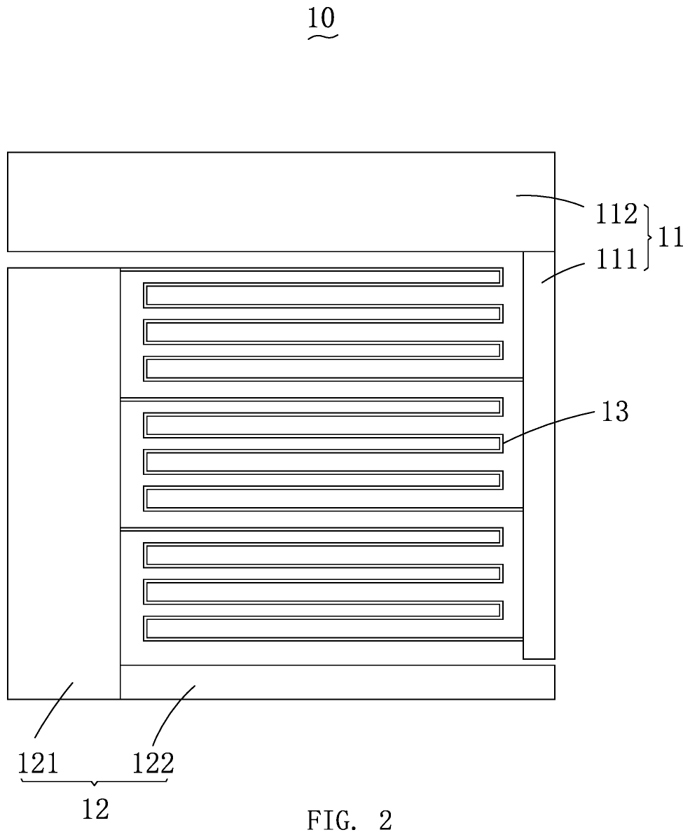

Referring to FIG. 1 and FIG. 2, the embodiment of the invention provides a MEMS conductive member 1. The MEMS conductive member 1 is composed of multiple conductive units 10. Each conductive unit 10 comprises a fixed member 11, a movable member 12 capable of reciprocating relative to the fixed member 11, and multiple groups of conductive coating layers 13 of electrically connecting the movable member 12 and the fixed member 11; each movable member 12 comprises a first surrounding wall 121 and a second surrounding wall 122 connected with the first surrounding wall 121; each fixed member 11 comprises a third surrounding wall 111 arranged opposite to the first surrounding wall 121, and a fourth surrounding wall 112 connected with the third surrounding wall 111 and arranged opposite to the second surrounding wall 122; and the multiple groups of conductive coating layers 13 are arranged at intervals and extend to the third surrounding walls 111 from the first surrounding walls 121 respectively.

In the embodiment, the structures of the movable members 12 and the fixed members 11 are reasonably arranged, and the fixed members 11 are electrically connected with the movable members 12 through the multiple groups of conductive coating layers 13 respectively, so that the MEMS conductive member 1 can allow elements (the fixed members 11 and the movable members 12) of transmitting signals at two ends to transmit electric signals during relative free displacement.

Referring to FIG. 1 and FIG. 2, the conductive coating layers 13 extend to the third surrounding walls 111 from the first surrounding walls 121 in a bent and detoured manner respectively. Through this design, the lengths of the conductive coating layers 13 can be increased under the same distance condition, so that the movement ranges of the movable members 12 can be increased.

Referring to FIG. 1 and FIG. 2, the projections of the conductive units 10 in the direction perpendicular to the extension directions of the conductive coating layers 13 are rectangular. The MEMS conductive member 1 is composed of four conductive units 10; four movable members 12 form an H-shape member 16 as a whole; every two fixed members 11 form a T-shape member 17 as a whole; two T-shape members 17 are positioned at two sides of the H-shape member 16 respectively; and the H-shape member 16 can reciprocate relative to the two T-shape members 17. The H-shape member 16 has the characteristics of less material and strong bearing capacity while the T-shape members 17 are formed for better cooperation with the H-shape member 16. Thus, the MEMS conductive member 1 has better overall structural stability.

It will be understood that the number of the conductive units 10 of forming the MEMS conductive member 1 may be set to four, may also be set to other number, is particularly set according to actual requirements and is not particularly limited here.

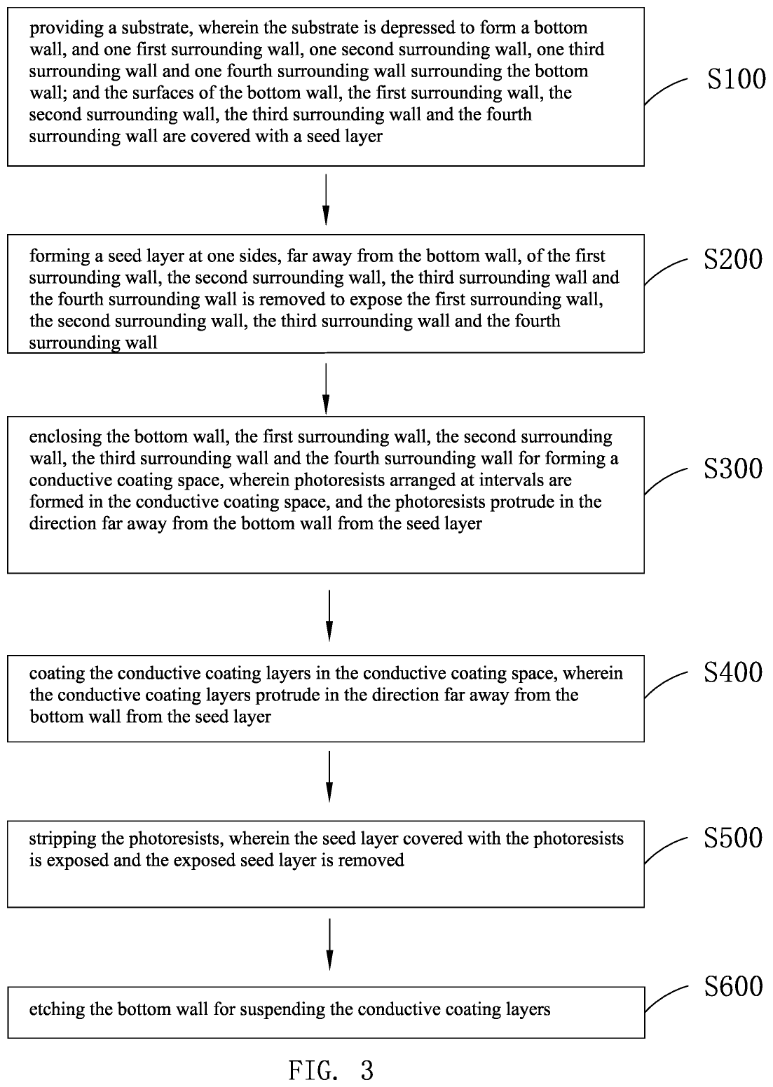

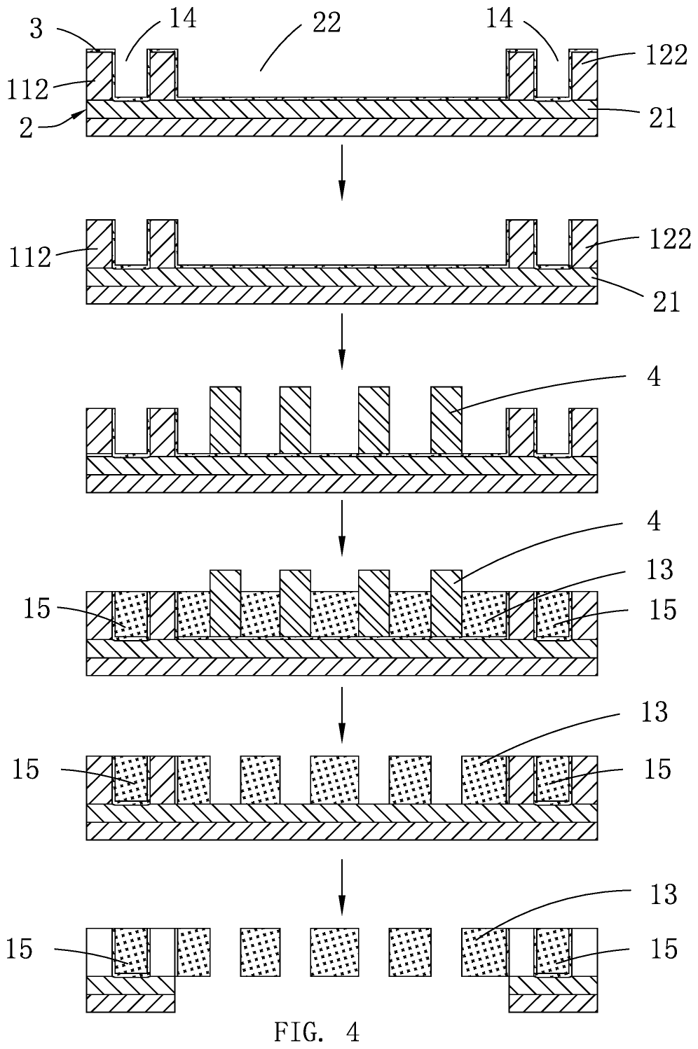

Referring to FIGS. 1 to 4, the embodiment of the invention further provides a preparation method of the conductive coating layers 13. The preparation method comprises a method for preparing the conductive coating layers 13 and comprises the steps:

51, a substrate 2 is provided, wherein the substrate 2 is depressed to form a bottom wall 21, and one first surrounding wall 121, one second surrounding wall 122, one third surrounding wall 111 and one fourth surrounding wall 112 surrounding the bottom wall 21; and the surfaces of the bottom wall 21, the first surrounding wall 121, the second surrounding wall 122, the third surrounding wall 111 and the fourth surrounding wall 112 are covered with a seed layer 3.

As an alternative embodiment, the seed layer 3 is a metal layer which is the same as the conductive coating layers 13 in material, and preferably, the seed layer may be metal or alloy with good conductivity.

S2, the seed layer 3 at one sides, far away from the bottom wall 21, of the first surrounding wall 121, the second surrounding wall 122, the third surrounding wall 111 and the fourth surrounding wall 112 is removed to expose the first surrounding wall, the second surrounding wall, the third surrounding wall and the fourth surrounding wall. In this step, a chemical mechanical polishing process can be adopted to remove the seed layer 3 at one sides, far away from the bottom wall 21, of the first surrounding wall 121, the second surrounding wall 122, the third surrounding wall 111 and the fourth surrounding wall 112 to expose the first surrounding wall, the second surrounding wall, the third surrounding wall and the fourth surrounding wall.

S3, the bottom wall 21, the first surrounding wall 121, the second surrounding wall 122, the third surrounding wall 111 and the fourth surrounding wall 112 are enclosed to form a conductive coating space 22.

Photoresists 4 are sprayed in the conductive coating space 22, the photoresists 4 arranged at intervals are etched after exposure and development, and the photoresists 4 protrude in the direction far away from the bottom wall 21 from the seed layer 3.

As an alternative embodiment, the photoresists 4 are uniformly arranged at intervals.

In this step, layers of the photoresists 4 with relatively large thicknesses are formed by selecting the photoresists 4 of which the viscosity is greater than or equal to 6,000 centipoises in a mode of spraying the photoresists 4, and the thicknesses of the photoresists 4 are set to be 20-100 microns. Subsequent forming of the conductive coating layers 13 with relatively large thicknesses is facilitated by forming the photoresists with the relatively large thicknesses.

As an alternative embodiment, in this step, the mode of coating the photoresists 4 for multiple times may be selected, and a polyamide material may be selected by the photoresists 4.

S4, the conductive coating layers 13 are coated in the conductive coating space 22, and the conductive coating layers 13 protrude in the direction far away from the bottom wall 21 from the seed layer 3.

S5, the photoresists 4 are stripped, the seed layer 3 covered with the photoresists 4 is exposed and the exposed seed layer 3 is removed, so that the conductive coating layers 13 are insulated from each other.

As an alternative embodiment, in the step S5, the seed layer 3 at the positions corresponding to the photoresists 4 can be removed through an etching method. The seed layer 3 is very small in thickness as long as a protection effect and a subsequent seed electroplating effect can be achieved; therefore, the loss of the metal of the conductive coating layers 13 caused by removal of the relatively thin seed layer 3 through controlling etching process conditions in the etching process is very small and can be almost neglected.

S6, the bottom wall 21 is etched and removed to suspend the conductive coating layers 13; and at the moment, the conductive coating layers 13 extend to the third surrounding wall 111 from the first surrounding wall 121 in a bent and detoured manner.

It should be noted that, in order to more conveniently transmit is electric signals, concave parts 14 are formed in the second surrounding wall 122 and the fourth surrounding wall 112, and conductive welding trays 15 are prepared in the concave parts 14 of the second surrounding wall 122 and the fourth surrounding wall 112 while the conductive coating layers 13 are prepared. The conductive welding trays 15 are electrically connected with the conductive coating layers 13.

In the preparation method provided by the embodiment of the invention, the process of aligning the photoresists 4 and the conductive coating layers 13 is not required, so that the problem that the metal of the conductive coating layers 13 is damaged and residues exist due to the fact that the photoresists 4 cannot be completely aligned with the conductive coating layers 13 is completely avoid in the preparation process. The conductive coating layers 13 of the MEMS conductive member 1 are prepared by using the preparation method of the conductive coating layers 13 provided by the embodiment of the invention, so that the yield of the prepared MEMS conductive member 1 is greatly improved, the MEMS conductive member 1 with excellent flexibility can be obtained, and the obtained MEMS conductive member 1 can allow the elements transmitting the signals at two ends to transmit the electric signals during relative free displacement.

It is to be understood, however, that even though numerous characteristics and advantages of the present exemplary embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms where the appended claims are expressed.

What is claimed is:

1. A MEMS conductive member including multiple conductive units each comprising a fixed member, a movable member capable of reciprocating relative to the fixed member, and multiple groups of conductive coating layers of electrically connecting the movable member and the fixed member; wherein
each movable member comprises a first surrounding wall and a second surrounding wall connected with the first surrounding wall;
each fixed member comprises a third surrounding wall arranged opposite to the first surrounding wall, and a fourth surrounding wall connected with the third surrounding wall and arranged opposite to the second surrounding wall;
and the multiple groups of conductive coating layers are arranged at intervals and extend to the third surrounding walls from the first surrounding walls respectively.

2. The MEMS conductive member as described in claim 1, wherein the conductive coating layers extend to the third surrounding walls from the first surrounding walls in a bent and detoured manner respectively.

3. The MEMS conductive member as described in claim 1, wherein projections of the conductive units in the direction perpendicular to the extension directions of the conductive coating layers are rectangular; the MEMS conductive member is composed of four conductive units; four movable members form an H-shape member as a whole; every two fixed members form a T-shape member as a whole; two T-shape members are positioned at two sides of the H-shape member respectively; and the H-shape member can reciprocate relative to the two T-shape members.

4. A preparation method of the conductive coating layers as described in claim 1, comprising steps of:
S1, providing a substrate, wherein the substrate is depressed to form a s bottom wall, and one first surrounding wall, one second surrounding wall, one third surrounding wall and one fourth surrounding wall surrounding the bottom wall; and the surfaces of the bottom wall, the first surrounding wall, the second surrounding wall, the third surrounding wall and the fourth surrounding wall are covered with a seed layer;
S2, forming a seed layer at one sides, far away from the bottom wall, of the first surrounding wall, the second surrounding wall, the third surrounding wall and the fourth surrounding wall is removed to expose the first surrounding wall, the second surrounding wall, the third surrounding wall and the fourth surrounding wall;
S3, enclosing the bottom wall, the first surrounding wall, the second surrounding wall, the third surrounding wall and the fourth surrounding wall for forming a conductive coating space, wherein photoresists arranged at intervals are formed in the conductive coating space, and the photoresists protrude in the direction far away from the bottom wall from the seed layer;
S4, coating the conductive coating layers in the conductive coating space, wherein the conductive coating layers protrude in the direction far away from the bottom wall from the seed layer;
S5, stripping the photoresists, wherein the seed layer covered with the photoresists is exposed and the exposed seed layer is removed; and
S6, etching the bottom wall for suspending the conductive coating layers.

5. The preparation method of the conductive coating layers as described in claim 4, wherein a chemical mechanical polishing process is adopted in the step S2 to remove the seed layer at one sides, far away from the bottom wall, s of the first surrounding wall, the second surrounding wall, the third surrounding wall and the fourth surrounding wall to expose the first surrounding wall, the second surrounding wall, the third surrounding wall and the fourth surrounding wall.

6. The preparation method of the conductive coating layers as described in claim 4, wherein the thicknesses of the photoresists in the step S3 are set to be 20-100 microns.

7. The preparation method of the conductive coating layers as described in claim 6, wherein the photoresists are sprayed in the conductive coating space, and the photoresists arranged at intervals are etched after exposure and development.

8. The preparation method of the conductive coating layers as described in claim 7, wherein the viscosity of the photoresists is greater than or equal to 6,000 centipoises.

9. The preparation method of the conductive coating layers as described in claim 4, wherein the seed layer is a metal layer which is the same as the conductive coating layers in material.
